(19) United States
(12) Patent Application Publication
(10) Pub. No.: US 2005/0253282 A1
(43) Pub. Date: Nov. 17, 2005

(54) Temperature resistant hermetic sealing formed at low temperatures for MEMS packages

(76) Inventors: Daoqiang Lu, Chandler, AZ (US); John Heck, Berkeley, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/833,978

(22) Filed: Apr. 27, 2004

(51) Int. Cl. H01L 21/44

(52) U.S. Cl. 257/787

(57) ABSTRACT

Certain hermetically sealed devices, such as micro-electromechanical systems (MEMS), may be sensitive high processing temperatures. However, the seal should be able to withstand higher temperatures that may be encountered, for example during device operation. Hermetic sealing may be realized by a fluxless soldering approach that comprises solder combinations that contain a low-melting-point (LMP) component such as Indium (In) or Tin (Sn) and a high-melting-point (HMP) component such as gold (Au), silver (Ag), or copper (Cu). The LMP/HMP ratio is selected to be HMP component rich so that the LMP component is essentially depleted resulting in an intermetallic compound (IMC) that has a higher melting point than the original HMP/LMP processing temperature after bonding and thermal annealing.

### FIELD OF THE INVENTION

Embodiments of the present invention relate to hermetic sealing and, more particularly, to temperature resistant solder compositions for hermetic packaging applications.

### BACKGROUND INFORMATION

MEMS components such as varactors, switches and resonators may be environmentally sensitive and prone to contamination. For this reason, and particularly with radio frequency (RF) MEMS components, there may be a need for hermetic packaging. Such packaging protects the MEMS components from the outside environment. Further, the sealing materials should not give off any volatiles which themselves may contaminate the MEMS devices. Hence, soldering methods that rely on fluxes may not be suitable.

Conventionally, several approaches have been utilized for hermetic packaging of MEMS components. Ceramic packages with cavities that may be sealed are sometimes used in the defense industry. This approach, while reliable, may be cost prohibitive for many commercial applications.

A second approach is to use a glass frit to bond a wafer containing the MEMS components to a cover. However, this technique uses high temperature bonding that may not be suitable for all components utilized in some MEMS applications. In some cases, the glass frit occupies a large area that increases the size of the resulting product and therefore increases its costs. In some cases, the glass frit bonding technology uses wire bonds for electrical connections that may not be adequate in some applications, such as high frequency applications.

### BRIEF DESCRIPTION OF THE DRAWINGS

FIG. 1 is a top view of a MEMS switch device;

FIG. 2 is a side view of the MEMS switch device shown in FIG. 1;

FIG. 3 is a view of a hermetically sealed MEMS device, for example a switch, having lateral electrical feed throughs according to an embodiment of the invention;

FIG. 4 is a view of a hermetically sealed MEMS device having vertical feed throughs or vias according to another embodiment of the invention;

FIG. 5 is a diagram illustrating the bonding and annealing process for forming an intermatalic compound (IMC) hermetic seal according to embodiments of the invention;

FIG. 6 is a diagram illustrating an array of MEMS die; and

FIG. 7 is a diagram illustrating and array of MEMS die as shown in FIG. 6 with a hermetic sealing cap.

### DETAILED DESCRIPTION

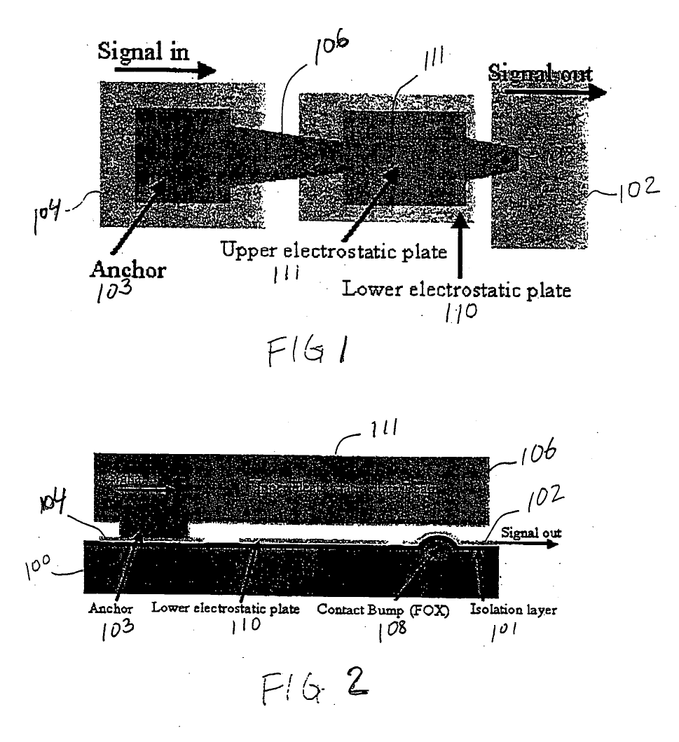

Referring to FIGS. 1 and 2, these figures illustrate a top view and a side view of a MEMS in-line cantilever beam metal contact series switch, respectively. The MEMS switch is used as an illustration as embodiments of the inventions may be applied to other types of MEMS components, such as varactors or resonators, that are to be packaged in a hermetic environment.

As shown, the switch may be formed on a substrate 100 having an isolation layer 101. A metalized signal line 102 may be formed on one side of the substrate 100 and a second signal line 104 may be formed on the second side of the substrate 100 over the isolation layer 101. A cantilevered beam 106 may be secured to the second signal line 104 with an anchor 103. A bump (electrode) 108 may be formed for example by a field oxide (FOX) technique under the first signal line 102. A lower electrostatic actuation plate 110 may be formed on the substrate 100 beneath an upper electrostatic actuation plate 111 formed in the cantilevered beam 106. When the actuation plate 110 is energized, by applying a voltage, the upper actuation plate 111, and thus the cantilevered beam 106, is pulled downward causing the bump 108 with the first signal line 102 to make contact with the cantilevered beam 106. This closes the switch and provides an electrical signal path between the first signal line 102 and the second signal line 104.

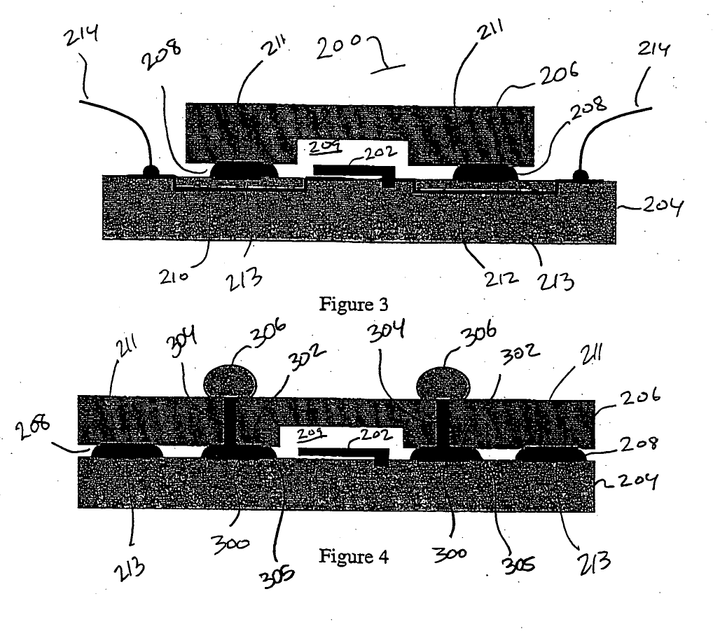

Referring now to FIG. 3, there is shown a schematic diagram that shows a hermetically sealed MEMS device 200. In this case, the MEMS device comprises a switch 202 as discussed above. The MEMS switch 202 may be formed on a semiconductor substrate 204. A cap 206 may be bonded to the semiconductor substrate 204 at a seal 208 that encloses the MEMS switch 202. The seal 208 may be in the form of a ring or closed loop that encases the MEMS switch 202 in a hermetically sealed space 209. One or more electrical conductors, 210 and 212, extend through the seal 208 to an exterior of the MEMS device 200. One or more wire bonds 214 may then be attached to the electrical conductors, 210 and 212.

Since the wire bonds 214 need adequate room for proper electrical connection additional real estate for the semiconductor substrate may be required. FIG. 4 is an alternate arrangement for electrically connecting the MEMS switch component 202 to the outside world. In this case, a plurality of bond pads 300 may also be formed on the semiconductor substrate 204. A seal ring 208 encircles the MEMS component 202. In one embodiment, the seal ring 208 forms a hermetic seal protecting the MEMS component 202 within an interior cavity 209. The sealing ring 208 may be between an adhesion layer 211 on the cap 206 and an adhesion layer 213 on the substrate 204. The adhesion layers 211 and 214 may be for example chromium (Cr) or other suitable material. Electrical connections between the bond pads 300 and the MEMS component 202 are not shown. Those skilled in the art will appreciate that various electrical connections may be formed on or within the semiconductor substrate 204 to accomplish this task. In one embodiment, a cap 206 has bond pads 302 that correspond with bond pads 300 on the substrate 204. Electrical vias 304 are shown within substrate cap 206. In one embodiment, the electrical vias 304 couple bond pads 300 from within the MEMS device to bond pads 302 on the exterior of the MEMS device. A solder joint 305 may be formed between the bond pads 300 and 302. A solder ball 306 may be positioned atop the electrical via 304 to allow the MEMS device to be easily bonded to an electrical interface.

As noted above, since the MEMS devices may be sensitive high temperatures, it is desirable to perform the hermetic sealing process at lower temperatures to avoid damage. However, it is also noted that the resulting seal should be able to withstand higher temperatures that may be encountered, such as during device operation, without failing. Such hemetically sealed MEMS devices may for example be part of a larger system such as used for switching applications in a radio frequency (RF) chip which may generate excessive temperatures.

According to embodiments of the invention, hermetic sealing may be realized by fluxless soldering approach that comprises solder combinations that contain a low-melting-point (LMP) component such as Indium (In) or Tin (Sn) and a high-melting-point (HMP) component such as gold (Au), silver (Ag), or copper (Cu).

The LMP/HMP ratio is selected to be HMP component rich so that the LMP component is essentially depleted resulting in an intermetallic compound (IMC) that has a higher melting point than the original HMP/LMP bonding temperatures and thermal annealing temperatures. Therefore, after bonding and annealing process, the sealing joints contain the HMP components and the IMC thusly formed, and can withstand higher temperatures because both HMP and IMC have high melting points than the LMP.

IMCs may be created when two dissimilar metals diffuse into one another creating species materials which are combinations of the two original materials. Conventional alloys generally comprise a disordered solid solution of one or more metallic elements and are typically described as a base material having certain percentages of other elements added. In contrast, an intermetallic compound is a particular chemical compound based on a definite atomic formula, with a fixed or narrow range of chemical composition. Various HMP/LMP materials may be used, for example Silver/Indium (Ag/In), Gold/Indium (Au/In), and Copper/Tin (Cu/Sn).

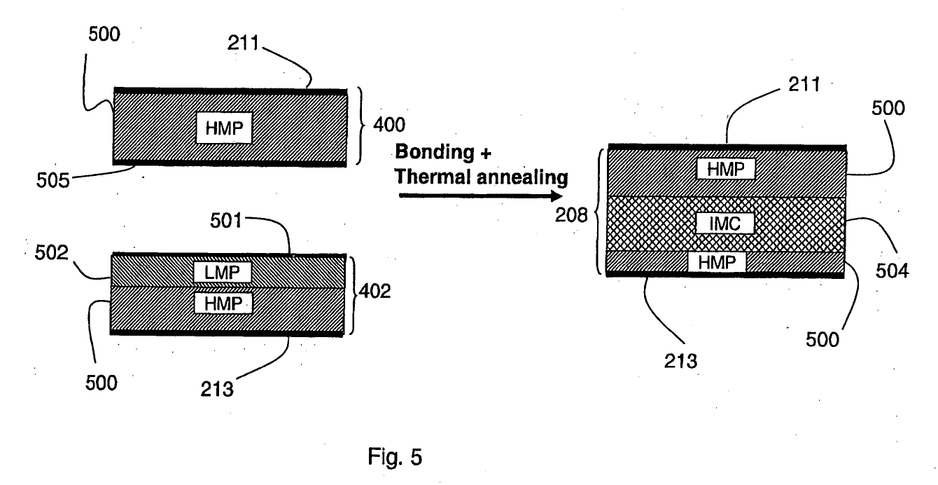

FIG. 5 shows a diagram illustrating the bonding and thermal annealing process creating an IMC according to embodiments of the invention. On the left side of the diagram, the adhesion layer 211 on the cap 206 (shown in FIGS. 3 and 4) has thereon a relatively thick layer of a high melting point material (HMP) 500, such as silver (Ag), gold (Au), or copper (Cu). A very thin protection layer 505 such as Au may be deposited on the top of the HMP layer 500 if the HMP 500 is a non-noble metal such as copper to prevent the oxidation of the HMP layer 500. The adhesion layer 211, HMP material 500 and the protection layer 505, may be collectively referred to as a cap sealing pad 400. The adhesion layer 213 on the substrate 204 (shown in FIGS. 3 and 4) has thereon a thick HMP layer 500, and a thinner layer of a low melting point material (LMP) 502 such as Indium (In), or Tin (Sn). A thin (e.g. 0.05-0.10 μm) protection layer 501 may be placed over the LMP material 502 to prevent oxidation of the LMP 502. The protection layer 501 may be Au. Upon deposition, the thin layer 501 may diffuse into the LMP material 502 and form a thin IMC layer. The adhesion layer 213, HMP layer 500, LMP material 502 and layer 501 may be collectively referred to as a substrate sealing pad 402. The cap sealing pad 400 and substrate sealing pad 402 may be brought into contact and bonded together at a given temperature for a period of time.

During bonding the LMP material 502 is caused to reflow (melt). The thin layer 501 of will break when the underlying thicker In or Sn layer begins to melt. Following the bonding process, the hermetic sealing ring is formed in an annealing process at a second temperature for a given time. During the bonding and annealing processes the LMP material 502 diffuses into the HMP material 500 until the LMP material 502 is essentially depleted. As shown in the left side of the diagram of FIG. 5, the resultant hermetic sealing ring 208 comprises two layers of the HMP material 500 and a layer of a newly created IMC material 504.

The table below shows example HMP/LMP mass ratios and layer thickness ratios for a number of materials as well as example temperature and time ranges for the bonding and annealing processes.

| | | HMP/LMP | | | |
|---|---|---|---|---|---|
| | | layer | | | IMC Final Re- |
| | HMP/LMP mass | thickness | Bonding | Annealing | melting |
| | ratio | ratio | Condition | Condition | Temp. |
| Cu—Sn | >1.6 | >1.4 | 230-300 C., | 230-280 C., | ˜600 C. |
| | | | 2-5 Min | 1-3 Hrs. | |
| Ag—In | >2.8 | >2.0 | 200-250 C., | 140-180 C., | ˜700 C. |
| | | | 2-5 Min | 10-24 Hrs. | |
| Au—In | >1.7 | >0.65 | 170-250 C., | 160-180 C., | ˜490 C. |
| | | | 2-5 Min | 1-5 Hrs. | |

As shown above, the bonding and annealing process of the HMP 500 and LMP 502 materials results in a high temperature IMC joint having a melting temperature far greater than the processing temperature used to create the joint. Thus, as shown in FIGS. 3 and 4, a hermetic sealing ring 208 may be formed by this technique at lower processing temperatures able to be withstood by the MEMs device 202. In addition, the hermetic seal 208 may be able to withstand much greater operating temperatures without re-melting.

Further, while the LMP material 502 and HMP material 500 are discussed and illustrated as initially being on the substrate 204 and the HMP 500 material as being on the cap 206, it will be appreciated that this association may be switched with the LMP material 502 and HMP material 500 being on the cap 206 and the HMP material 500 being on the substrate 204 prior to thermal processing in other embodiments of the invention.

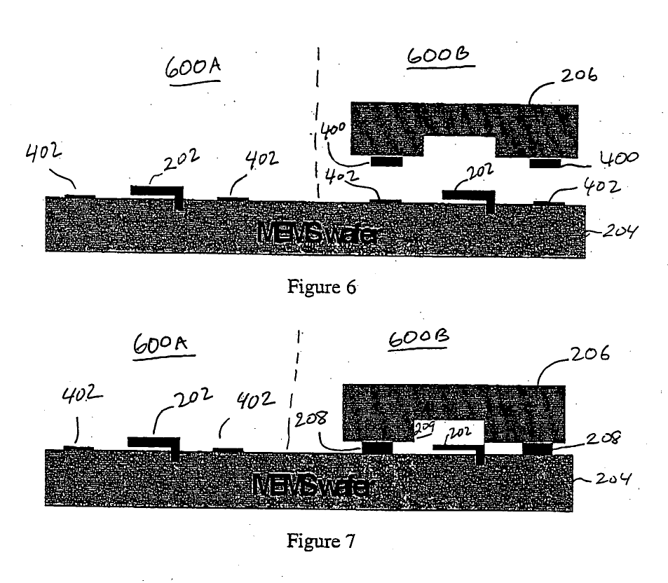

Referring to FIG. 6, an array of MEMs die may be created on a single substrate or wafer 204. In this instance, a first MEMS 600A die may be manufactured directly adjacent another MEMS die 600B. As shown, the MEMs die, 600A and 600B, may include substrate sealing pads 402 (described above with reference to FIG. 5) comprising the LMP material 502. In addition, a cap 206 may include a cap sealing pad 400 (also described above with reference to FIG. 5). While the cap 206 is shown as a single cap, it may be appreciated that the cap 206 may also comprise a wafer level array of caps for capping both die 600A and 600B at once. The cap 206 may be picked up and the sealing pads 400 and 402.

As shown in FIG. 7, after the bonding and annealing process described above, a sealing ring 208 comprising the IMC material encases the MEMs device 202 in a hermetic enclosure 209. The MEMS die 600A and 600B may be later singulated in a dicing process.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

1. An apparatus having a temperature resistant hermetic seal, comprising:
a substrate;
an environmentally sensitive device on the substrate;
a cap to fit over the device; and
a hermetic seal between the cap and the substrate, the hermetic seal comprising:
high melting point (HMP) component and an intermetallic compound (IMC) formed from the HMP component and a low melting point (LMP) component with a processing temperature, the IMC having a higher melting temperature than the processing temperature.

2. The apparatus as recited in claim 1 wherein the HMP component comprises Copper (Cu) and the LMP component comprises Tin (Sn) at a HMP/LMP mass ratio greater than 1.6 and a HMP/LMP layer thickness ratio greater than 1.4.

3. The apparatus as recited in claim 2 wherein a processing temperature of the HMP component and LMP component is in an approximate range of 230 and 300 degrees Celsius and a melting point of the IMC is approximately 600 degrees Celsius.

4. The apparatus as recited in claim 1 wherein the HMP component comprises Silver (Ag) and the LMP component comprises Indium (In) at a HMP/LMP mass ratio greater than 2.8 and a HMP/LMP layer thickness ratio greater than 2.0.

5. The apparatus as recited in claim 4 wherein a processing temperature of the HMP component and LMP component is in an approximate range between 140 and 250 degrees Celsius and a melting point of the IMC is approximately 700 degrees Celsius.

6. The apparatus as recited in claim 1 wherein the HMP component comprises Gold (Au) and the LMP component comprises Indium (In) at a HMP/LMP mass ratio greater than 1.7 and a HMP/LMP layer thickness ratio greater than 0.65.

7. The apparatus as recited in claim 6 wherein a processing temperature of the HMP component and LMP component is in an approximate range between 160 and 250 degrees Celsius and a melting point of the IMC is approximately 490 degrees Celsius.

8. A method of forming a temperature resistant hermetic seal, comprising:
depositing a substrate adhesion layer on a substrate surrounding a device;
depositing one of a low melting point (LMP) component and a high melting point (HMP) component on the substrate adhesion layer;
depositing a cap adhesion layer on a cap;
depositing the other of a LMP component and a HMP component on the cap adhesion layer;
depositing a thin layer of the HMP component on the LMP compenent;
aligning the cap over the substrate;
bonding the cap to the substrate at a bonding temperature; and
annealing the cap and substrate at an annealing temperature to form an intermetallic component (IMC) having a melting temperature greater that said bonding temperature and said annealing temperature.

9. The method as recited in claim 9, wherein the HMP component comprises Copper (Cu) and the LMP component comprises Tin (Sn) at a HMP/LMP mass ratio greater than 1.6 and a HMP/LMP layer thickness ratio greater than 1.4.

10. The method as recited in claim 9 the bonding temperature is in an approximate range of 230 and 300 degrees Celsius and the annealing temperature in an approximate range of 230-280 degrees Celsius for 1-3 hours and the melting temperature of the IMC is approximately 600 degrees Celsius.

11. The method as recited in claim 9 wherein the HMP component comprises Silver (Ag) and the LMP component comprises Indium (In) at a HMP/LMP mass ratio greater than 2.8 and a HMP/LMP layer thickness ratio greater than 2.0.

12. The method as recited in claim 11 wherein the bonding temperature is in an approximate range between 200 and 250 degrees Celsius and the annealing temperature is in an approximate range of 140-180 degrees Celsius for 1-24 hours, and the melting temperature of the IMC is approximately 700 degrees Celsius.

13. The method as recited in claim 9 wherein the HMP component comprises Gold (Au) and the LMP component comprises Indium (In) at a HMP/LMP mass ratio greater than 1.7 and a HMP/LMP layer thickness ratio greater than 0.65.

14. The method as recited in claim 13 wherein the bonding temperature is in an approximate range between 170-250 degrees Celsius, and the annealing temperature is in an approximate range of 160-180 degrees Celsius for 1-5 hours, and the melting point of the IMC is approximately 490 degrees Celsius.

15. A method as recited in claim 9 wherein the substrate adhesion layer and the cap adhesion layer comprises Chromium (Cr).

16. A hermetically sealed micro-electromechanical system (MEMS), comprising:
a MEMS device disposed on a substrate;
a cap to fit over the MEMS device;
a hermetic sealing ring formed between the cap and the substrate, the sealing ring comprising a high melting point component (HMP) and an intermetallic compound (IMC) formed from the HMP and a low melting point (LMP) component.

17. The hermetically sealed micro-electromechanical system (MEMS) as recited in claim 16 wherein said HMP component comprises Copper (Cu) and the LMP component comprises Tin (Sn) at a HMP/LMP mass ratio greater than 1.6 and a HMP/LMP layer thickness ratio greater than 1.4.

18. The hermetically sealed micro-electromechanical system (MEMS) as recited in claim 16 wherein the HMP component comprises Silver (Ag) and the LMP component comprises Indium (In) at a HMP/LMP mass ratio greater than 2.8 and a HMP/LMP layer thickness ratio greater than 2.0.

19. The hermetically sealed micro-electromechanical system (MEMS) as recited in claim 16 wherein the HMP component comprises Gold (Au) and the LMP component comprises Indium (In) at a HMP/LMP mass ratio greater than 1.7 and a HMP/LMP layer thickness ratio greater than 0.65.

20. The hermetically sealed micro-electromechanical system (MEMS) as recited in claim 16 wherein said sealing is between a chromium (Cr) adhesion layers on the cap and the substrate.

21. The hermetically sealed micro-electromechanical system (MEMS) as recited in claim 16 wherein said MEMS device is contained on a radio frequency (RF) chip.
